(19) United States
(12) Patent Application Publication
(10) Pub. No.: US 2025/0094682 A1
(43) Pub. Date: Mar. 20, 2025

(54) Analog ECO Flow

(71) Applicant: Taiwan Semiconductor Manufacturing Company, Ltd., Hsinchu (TW)

(72) Inventors: Ayushi Agrawal, Hsinchu (TW); Yu-Tao Yang, Hsinchu (TW); Ming-Cheng Syu, Hsinchu (TW); Wen-Shen Chou, Hsinchu (TW); Yung-Chow Peng, Hsinchu (TW)

(21) Appl. No.: 18/470,539

(22) Filed: Sep. 20, 2023

(51) Int. Cl. G06F 30/398; G06F 30/394

(52) U.S. Cl. CPC G06F 30/398; G06F 30/394

(57) ABSTRACT

Methods of designing integrated circuits incorporating an analog ECO flow are provided. An example method comprises receiving an initial design and performing an auto-marker process. The auto-marker process comprises performing a first auto-marker process to surround a first plurality of active cells of the design with first computer-aided design (CAD) layers corresponding to a first plurality of engineering change order (ECO) cells, performing an enhanced auto-marker process to cover irregular shapes of the design with second CAD layers corresponding to a second plurality of ECO cells, and performing a second auto-marker process to fill empty areas of the design with third CAD layers corresponding to a third plurality of ECO cells. The method further includes filling the design with the first plurality of ECO cells, the second plurality of ECO cells, and the third plurality of ECO cells.

### BACKGROUND

In integrated circuit (IC) design, an engineering change order (ECO) process is often employed to modify a layout at late stages of the design or after tapeout. By implementing an ECO, a designer may incorporate changes to rectify errors or optimize performance without needing to undergo a complete and costly re-design.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flowchart depicting a design method according to an embodiment.

FIG. 2 is a flowchart depicting a method of designing an integrated circuit according to an embodiment.

FIG. 3 is a flowchart and accompanying schematics depicting an auto-marker process according to an embodiment.

FIG. 4 is a schematic diagram depicting an auto-marker process according to an embodiment.

FIG. 5 is a schematic diagram depicting ECO cell areas formed by an auto-marker process according to an embodiment

FIG. 6 is a schematic flow depicting an auto-marker process according to an embodiment.

FIG. 7 is a flowchart and accompanying schematics depicting an auto-marker process according to an embodiment.

FIG. 8 is a schematic diagram depicting an auto-marker process according to an embodiment.

FIG. 9 is a flowchart depicting a corner checking flow according to an embodiment.

FIG. 10 is a schematic diagram depicting phases of a corner checking flow according to an embodiment.

FIG. 11 is a flowchart and accompanying schematics depicting a DRC pre-checker according to an embodiment.

FIG. 12 shows schematic diagrams depicting a layout of a design after an analog ECO process according to embodiments.

FIGS. 13A, 13B, and 13C are block diagrams depicting example systems for implementing approaches described herein for designing integrated circuits.

FIG. 14 is a flowchart depicting a method of implementing a design change to an integrated circuit according to an embodiment.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in some various examples. This repetition is for the purpose of simplicity and clarity and does not in itself dictate a relationship between some various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the circuit. Some of the features described below can be replaced or eliminated for different embodiments. Although some embodiments are discussed with operations performed in a particular order, these operations may be performed in another logical order.

As described above, an ECO process may be incorporated into an IC design process to allow for efficient implementation of design changes and modifications. Even still, introducing a design change may be a lengthy and expensive process. Increasing complexity of circuit designs and fabrication processes, particularly in circuits employing analog cells, has led to larger time periods between design tapeout and wafer completion. Additionally, implementing some design changes may include changing a mask used during processing, which further increases the fabrication time and cost. Accordingly, the time and cost for a particular design to go from initial stages, through testing, and enter into production may be very large.

To facilitate ECOs and speed up design changes, ECO cells may be inserted into a design floorplan. These cells may comprise pre-determined architecture selected to provide a specific function based on design need. ECO cells may be strategically placed throughout a design in order to replace functional cells that fail or to enable changes to be made to a layout without a complete redesign.

The present subject matter introduces ECO cells into analog designs and provides an analog ECO flow to enable efficient ECOs for circuits employing analog cells. This analog ECO flow may support early ODPO (oxygen diffusion and polysilicon) tapeout leading to shorter turn-around time (TAT) when implementing changes. Furthermore, this flow may reduce the time-to-market for designs and improve process costs by facilitating updates of back-end-of-line (BEOL) masks.

Embodiments described herein may provide an auto-marker process that can fill an ECO computer-aided-design (CAD) with higher efficiency. Additionally, embodiments described herein may provide pre-checking and corner checking solutions that avoid false design-rule check (DRC) errors caused be implementing ECOs. Introducing ECO cells and employing the analog ECO flow may enhance productivity between initial IC design and final product. In some embodiments, the ECO cells may be filled into the design at more than a 70% efficiency.

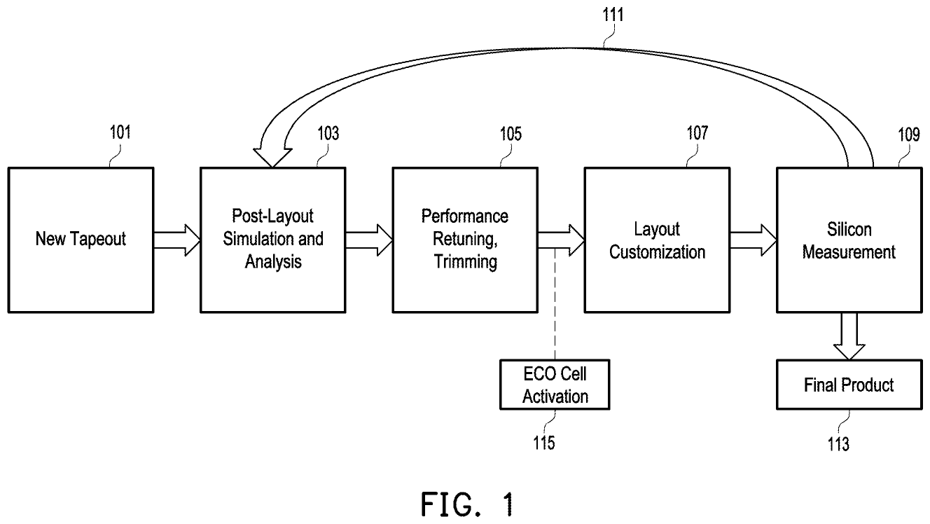

FIG. 1 is a flowchart depicting a design method according to an embodiment. An example analog ECO flow may begin at 101 with a new tapeout of an initial design. In an embodiment, the new tapeout may be optimized for improved metrics such as power, performance, and area (PPA). Generally, increasing PPA has a negative impact on TAT during production. Embodiments described herein, may offer products having strong PPA characteristics without compromising TAT. As a part of the tapeout process 101, a front-end-of-line (FEOL) mask may be manufactured. The FEOL mask may be used to transfer patterns of active components of the integrated circuit onto a silicon wafer. FEOL mask manufacturing may be time-consuming and costly. An advantage of embodiments described herein may be that design changes can be implemented without returning to this step and manufacturing a new FEOL mask.

The flow may then proceed to post-layout simulation and analysis at 103. During this phase the taped-out design may be evaluated for compliance with design constraints. For example, at this stage rule checks such as a design rule check may be performed, parasitic extraction may occur, along with other analysis such as timing analysis and noise analysis.

Next, the design may undergo performance re-tuning, and trimming at 105. Here, based on the results of the simulation and analysis, the design may be re-tuned and optimized, and components of the design may be trimmed, for example by laser trimming, to obtain desired electrical characteristics.

Following re-tuning and trimming, the flow may proceed to layout customization at 107. During layout customization, designers may modify or optimize the physical layout of components of the design to improve characteristics and meet constraints. As non-limiting examples, a designer may modify the layout for area optimization or performance optimization purposes.

After layout customization, the flow may proceed to silicon measurement at 109, where the customized design on the actual silicon wafer may be tested and verified to validate functionality. Upon completion of silicon measurement, the final product may be ready to enter the market as indicated at 113. However, in other instances, design changes may be called for, in which case the flow may return to a previous stage, as indicated by 111.

In an embodiment, the ECO cells and analog ECO flow may allow for design changes to be implemented by returning to the post-layout simulation and analysis phase 103. This may obviate the need to create a new FEOL mask, which is a costly and time consuming process.

After a design change, the flow may proceed in the same manner as described above. However, by using ECO cells according to embodiments of the present subject matter, the process may be streamlined. After completing analysis, re-tuning, and trimming, the flow may involve activating ECO cells in the design as shown at 115. The called for design changes may be implemented by activating and strategically using these ECO cells, rather than requiring a new mask as described above. After ECO cell activation, the flow may then proceed through layout customization 107 and silicon measurement 109 to the final product 113.

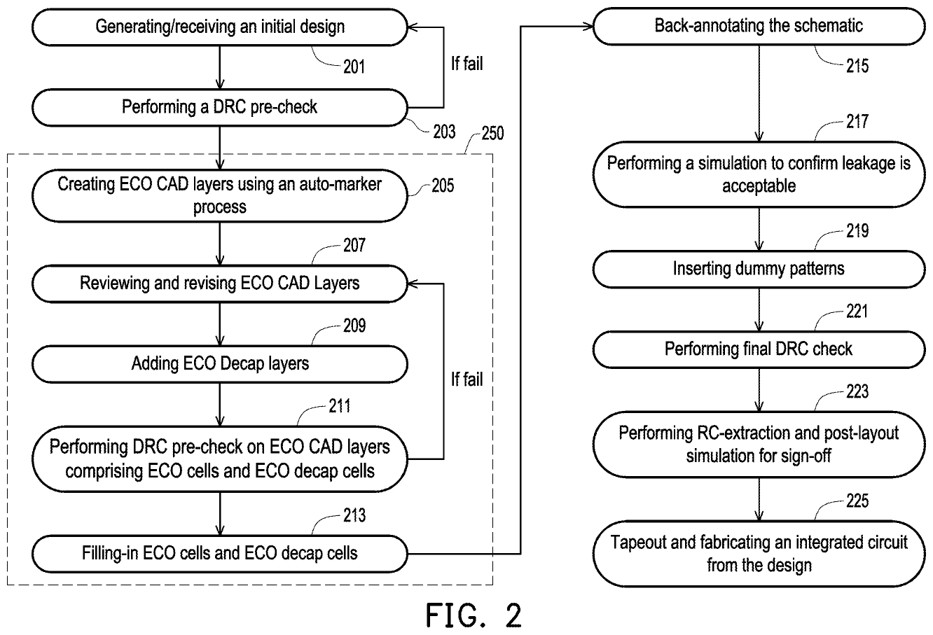

FIG. 2 is a flow diagram depicting a method of designing an integrated circuit according to an embodiment. The method of design may incorporate an analog ECO flow configured to insert ECO cells into the design. The method may begin at 201 by generating or receiving an initial design. A designer may generate the initial design and the initial design may be received and taken as input by software design tools such as EDA or CAD tools. The initial design may be a finished active design comprising schematics and a layout of a circuit design. In an embodiment, the initial design may comprise an IP design, wherein a designer integrates customizable, reusable IP blocks, including predesigned circuits and functionality, into a layout.

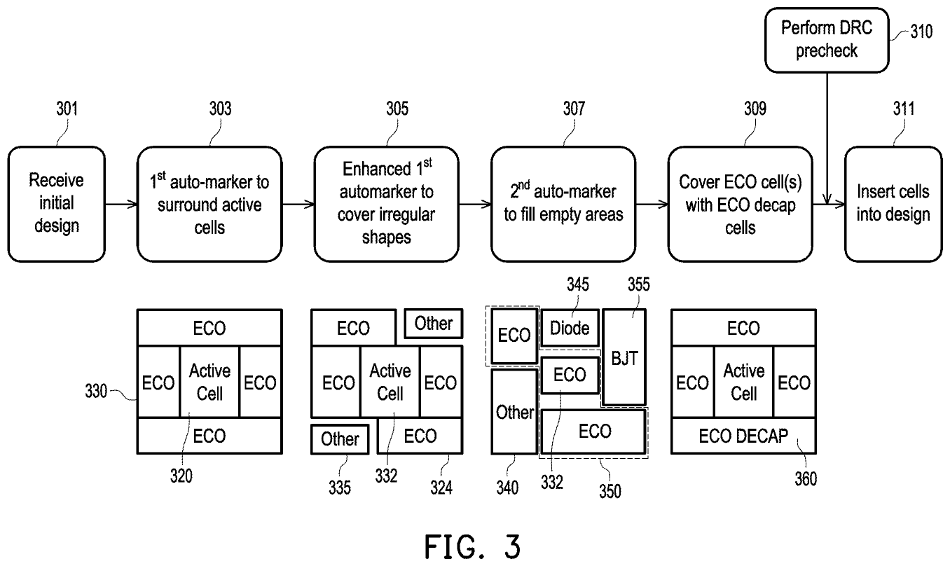

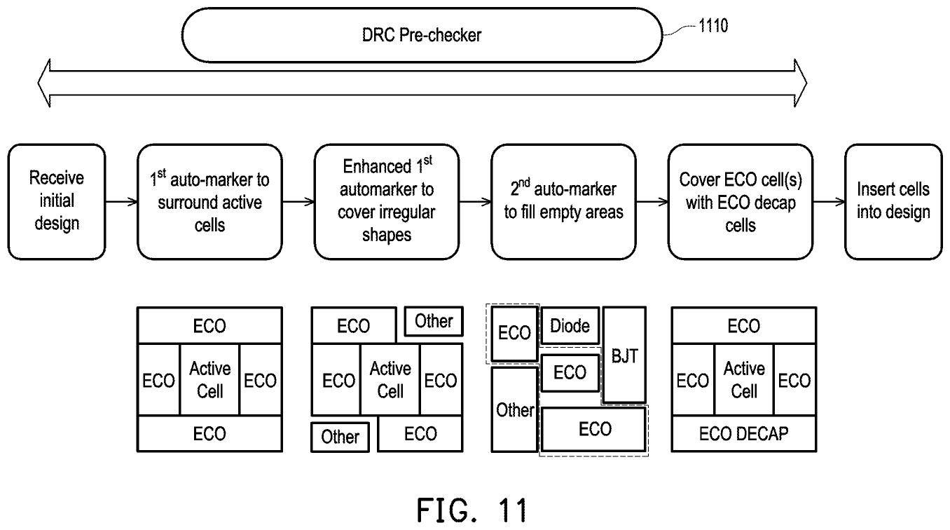

Next the method may proceed to 203 where the design may undergo a pre-checking process that evaluates for the design for any DRC issues prior to inserting ECO cells. A pre-checker according to the present subject matter will be described in more detail below with respect to FIG. 3 and FIG. 11. If the design fails the pre-check process, the flow may return to 201 where the floorplan may be altered in order to avoid the DRC issue. If the pre-check does not identify any issues, the flow may proceed into an analog ECO flow 250. The analog ECO flow 250 may comprise a series of processes culminating in the insertion of ECO cells into the design data.

At 205, ECO CAD layers may be drafted using an ECO auto-marker flow. The auto-marker flow may insert design layers that correspond to ECO cells, as well as other types of cells in order to fill-in an ECO CAD layer. The ECO CAD layers may each comprise a particular layer-level of an IC build-up having multiple layers. The auto-marker process may be automated, and may be initiated by a designer after the initial design is generated and DRC pre-check is performed. The auto-marker flow may proceed in a series of phases, and may further comprise a corner checking flow. The auto-marking process is described in more detail below with respect to FIGS. 3-10.

After the ECO CAD layers are drafted, these layers may be reviewed and revised by a designer at 207. In an embodiment, the review and revise process is manually performed. The ECO CAD layer design may be reviewed for coincidence with a plurality of pre-defined layer designs. A designer may modify a layer, as created by the auto-marker flow, to ensure that it tracks with one of the pre-defined layer types.

Next, the method may proceed to 209 and decoupling capacitor (Decap) layers corresponding to decap cells may be added to the design. In an embodiment, the decap cells may comprise ECO decap cells that provide a decap function while also enabling an ECO in the event of a design change. For example, a called-for design change may change the power characteristics of the design. By strategically placing ECO decap cells into the design, an ECO implemented to enact the called-for design change may use these ECO decap cells to achieve desired characteristics. This may save time and costs associated with inserting new decap cells along with an ECO, and may ensure that the design does not suffer from less than optimal performance due to a lack of correctly placed decap cells. In an embodiment, ECO decap cells may be manually placed by a designer's instructions or commands. The design tool being used may receive this instruction or command from the designer, and place the ECO decap cells into the design in a corresponding position.

After ECO decap layers are placed to define ECO decap cells, another pre-check may occur at 211 to ensure that the ECO CAD layers including ECO decap layers do not trigger any DRC violations. If any rules are violated, the method may return to 207 and the ECO CAD layers may be revised again to eliminate any violations. If no rules are violated, the method may proceed to the next phase.

At 213, the ECO cells and ECO decap cells are filled into the design from the ECO CAD layers. In an embodiment, the fill-in process may be automated or performed by a software tool. For example, an electronic design automation (EDA) tool may fill the design with ECO cells and ECO decap cells at the locations verified by the pre-check in 211. Once these cells are filled in, the design may proceed to final checks and processing before final tapeout.

In an embodiment, the method next proceeds to 215 where the schematic may be back-annotated to update the decap cell locations. Back-annotating may allow the designer to keep the design up-to-date with the layout. By back-annotating the design with the decap, a designer may allow for more efficient implementation of design changes and ECOs if desired.

After, back-annotation, the method may proceed to 217 where simulations are performed to confirm whether the leakage level is acceptable. If the leakage level is not acceptable, the designer may tie-off one or more of the decap cells. If the leakage is deemed acceptable, the method may proceed to the next phase.

At 219, dummy patterns may be inserted into the design. These patterns may allow the physical design to achieve a more uniform pattern and mitigate the occurrence of dishing and other abnormalities leading to poor performance. In an embodiment, dummy patterns may be inserted by a dummy utility system.

Next, a final DRC check may be performed at 221. This final DRC check may take all components of the design, including newly added dummy features, into consideration. Including final DRC check 221 may ensure that all spacing is proper and may mitigate the potential for device failure after fabrication.

Following the final DRC check 221, RC extraction and additional post-layout simulation may be performed at 223 to prepare the design for final sign-off. RC extraction may determine the parasitic resistance and capacitance through the design by analyzing the layout. The determined parasitic resistance and capacitance values may then be used in post-layout simulations in order to accurately simulate performance of a device fabricated from the design.

After RC extraction and post-layout simulation is conducted, the method may proceed to tapeout at 225. In an embodiment, tapeout may comprise processing the design and fabricating an integrated from the design. For example, a designer may consider the results of the simulations and determine that the design is ready for fabrication, and may then cause an integrated circuit to be fabricated from the design. This is generally the final stage for an integrated circuit design; however, in some instances future design changes may be needed. By incorporating ECO cells throughout the design, the analog ECO flow according to embodiments described herein may facilitate efficient ECOs in the event of a future design change.

FIG. 3 is a flowchart and accompanying schematics depicting an auto-marker process according to an embodiment. In an embodiment, the auto-marker process may proceed in a series of phases. A first auto-marker phase may be utilized to surround active, analog cells of the design, and a second auto-marker phase may fill in empty areas of the design.

The auto-marker process may begin at 301 where an initial design is received. Similar to the flow described above with respect to FIG. 2, the initial design may be a finished active design. In an embodiment, the active design may comprise a plurality of active cells. The active cells may comprise pre-determined standard architectures that are selected to provide a specific function. In an embodiment, the active cells may comprise analog cells. These cells may be designed to comprise specific internal arrangements of transistors, capacitors, or other components sufficient to provide their designated function. For example, the analog cells may comprise amplifiers, regulators, comparators, filters, or any other type of analog cell as called for by the specific design. Architectures for the analog cells may be stored in, and recalled from, an analog cell library, allowing designers of the initial design to create complicated and densely packed integrated circuits with reduced time and effort.

After the initial design is received, a first auto-marker process begins at 303. In this phase, the auto-marker process surrounds active cells 320 of the design with first ECO cells 330. The first ECO cells 330 may also comprise pre-determined standard architecture configured to provide a specific function. In an embodiment, first ECO cells 330 may comprise the same cell type as the active cell 320 which they surround. This may facilitate an efficient ECO if an active cell 320 fails, in which case the one of the surrounding ECO cells may be routed into the design to take its place. Unlike active cells 320, however, the first ECO cells 330 are not initially routed together with other components of the design. This may preserve first ECO cells 330 as placeholders capable of being integrated into the design during an ECO process to implement a design change.

After ECO cells are inserted to surround analog cells, an enhanced auto-marker process may be applied at 305 to cover areas where portions of the design have irregular shapes. For example, a second active cell 322 may be in close proximity with other cells of the design 335. The presence of the other cells 335 inhibits the ability of the auto-marker process to fully insert ECO cells into all empty space. Accordingly, the enhanced auto-marker process may be employed to insert second ECO cells 324 into these areas in order to fill-in as much as possible without covering up pre-existing design data, or violating any design rules. In an embodiment, second ECO cells 324 may comprise a same cell type as second active cells 322.

Once analog cells of the design have been surrounded by ECO cells by the first auto-marker process, a second auto-marker process may begin at 307. In an embodiment, the second auto-marker process may fill “true empty” areas 350 of the design with third ECO cells 332. For example, the design may incorporate a number of components including a diode 345, a bi-polar junction transistor (BJT) 355, and other components 340. These components may include any type of cell or IC elements as desired by the designer.

In the design, these positions of these components may create empty space in the design indicated by dashed line 350. To maximize efficiency, the auto-marker process aims to fill as much of this empty space as possible with third ECO cells 332. In an embodiment, the third ECO cells filled within true empty areas may comprise CMOS analog cells. This may preserve flexibility for future functionality of the ECO cells in response to a design change.

After the second auto-marker process, ECO cells may be covered with ECO decap cells 360 at 309. In an embodiment, this may be a manual process in which a designer covers ECO cells with ECO decap cells based on desired functionality and electrical characteristics. Next, at 310, a DRC pre-check may be performed on all ECO CAD layers included those with manually entered ECO decap cells. This DRC pre-check may comprise the DRC pre-check process 211 discussed above with respect to FIG. 2. If no rules are found to be violated, the cells may be inserted into the design at 311.

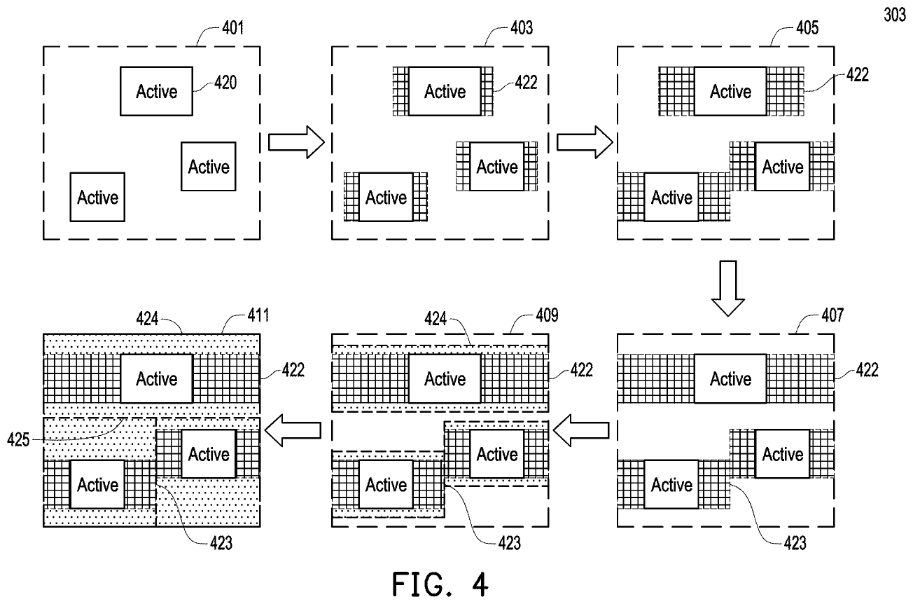

FIG. 4 is a schematic diagram depicting first auto-marker process 303 according to an embodiment. In an embodiment, the first auto-marker process 303 may begin at 401 with an initial design comprising a plurality of active cells 420. The active cells 420 may comprise analog cells as described above with respect to FIG. 3. Next, at 403, the auto-marker process may create first ECO boxes 422 that extend, in a first direction, from all active cells within the auto-marker area. These ECO boxes 422 represent areas into which ECO cells may be placed at a later stage of the design process.

For example, the first direction may be the x-direction and the first ECO boxes 422 may be extended from a top edge to a bottom edge of each active cell. The first ECO boxes 422 in the first direction may be extended in a series of steps, with each step comprising an extension of a pre-defined minimum width. For example, 403 shows each active cell 420 with a first extension of the minimum width. This extension continues until a conflict is detected between adjacent extensions.

When a conflict occurs, as shown in 405, the auto-marker designates the position of that conflict as a boundary for each extension in conflict. For example, as shown in 405, two ECO boxes of adjacent active cells come may come into conflict creating a boundary 423. This boundary 423 delineates the outer edges of ECO cells that may be formed in this area. The process may continue at 407 where, while extensions that have come into conflict stop extending, first ECO boxes 422 having no conflict continue to extend to the boundary of the area subject to the auto-marker process.

Next, having set the boundaries for ECO cells in the first direction, the process may proceed at 409, and second ECO boxes 424 may be created in the second direction. For example, the second direction may be the y-direction. In an embodiment, each second ECO box 424 may have a length in the first, or x, direction equal to a span of each active cell in that direction plus the span of the ECO boxes 422 on each side of the active cell. Similar to first ECO boxes 422, second ECO boxes 424 may extend in a series of steps with each step comprising an extension of a pre-defined minimum width.

As shown at 411, the second ECO boxes 424 may extend until adjacent ECO boxes come into contact with another. For example, second ECO boxes 424 from a first active cell may come into conflict with second ECO boxes 424 of second active cells at boundary 425. This boundary may delineate the edges of where ECO cells may be placed in the second direction. From this, the first auto-marker flow may identify empty areas into which ECO cells may be placed.

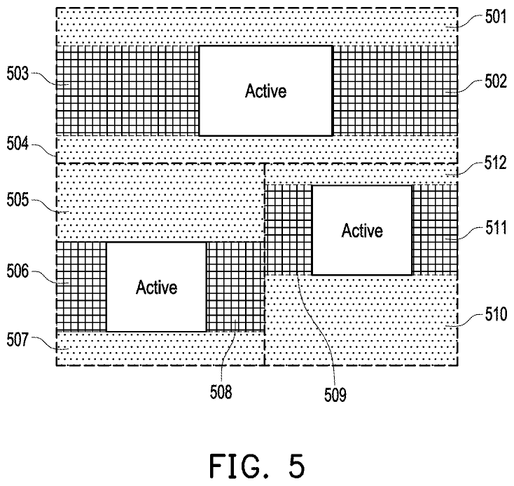

FIG. 5 is a schematic diagram depicting resultant ECO cell areas from the first auto-marker process according to an embodiment. For example, FIG. 5 may correspond to the design at 411 as described above. In this example, the first auto-marker flow may identify twelve rectangular areas, labeled 501-512 in FIG. 5, into which an ECO cell may be placed. Each ECO cell area has edges defined by either the outer perimeter of the auto-marker area, or a boundary between extensions of adjacent active cells.

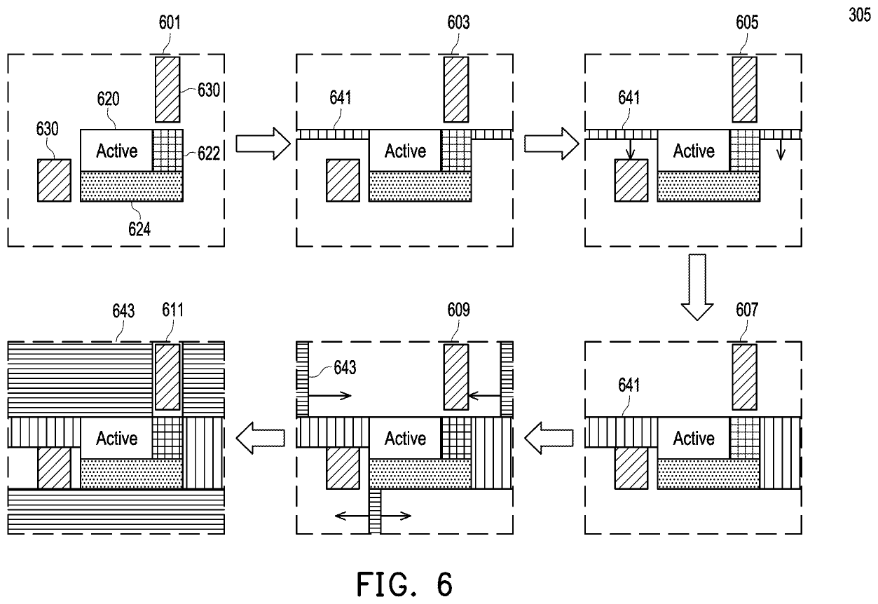

FIG. 6 is a schematic flow depicting an enhanced auto-marker process 305 according to an embodiment. The design may comprise an active, analog cell 620 along with a plurality of other cells 630. The presence of these other cells may make forming the ECO boxes of the first auto-marker process more difficult. Accordingly, an enhanced auto-marker process may be introduced to fill-in irregular shapes. At 601, the design may include first ECO boxes 622 and second ECO boxes 624 formed according to the process described above with respect to FIG. 4.

At 603, third ECO boxes 641 may be created to delineate empty space into which ECO cells may be filled. In an embodiment, these ECO boxes may be created to align with upper edges of the active cell 620 and may extend to the boundary of the auto-marker area. For example, third extensions 641 may grow first in the x-direction towards the perimeter of the auto-marker area before being extended in the y-direction to fill the empty space.

At 605, the third ECO boxes may then be extended in the second, y-direction until a conflict is detected. For example, as shown at 604, a third ECO box 641 may come into conflict with one of the other cells 630 causing the auto-marker process to set a boundary for that area. Another third ECO box 641 may reach the bottom boundary of the second ECO box 624. Accordingly, the auto-marker process may set this as the boundary for that particular third ECO box. In other embodiments, however, the rules of the process may be set such that this third ECO box extends fully to the perimeter edge of the auto-marker area.

Next, at 609, fourth ECO boxes 643 may be created to fill as much of the remaining empty space as possible. Fourth ECO boxes 643 may grow first in the y-direction toward the perimeter of the auto-marker area. As shown at 611, once fourth ECO boxes 643 have extended a maximum distance in the y-direction, they may then be extended in the x-direction until coming into conflict with existing structures. By incorporating this enhanced auto-marker process, even design areas having irregular shapes may obtain a high rate of coverage by ECO cells.

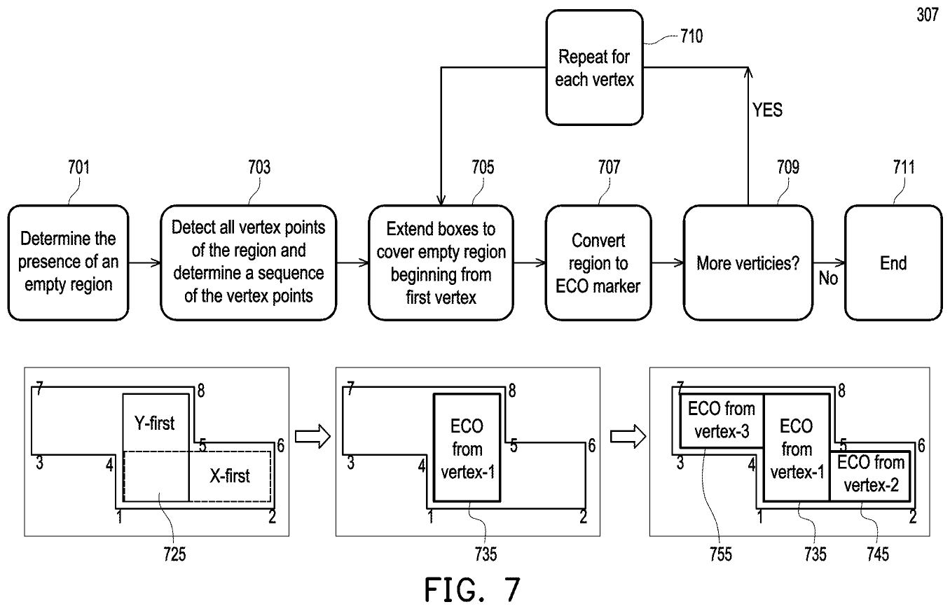

FIG. 7 is a flowchart and accompanying schematics depicting a second auto-marker process 307 according to an embodiment. The second auto-marker process may be employed to fill true empty space with ECO cells. In an embodiment, the second auto-marker process may begin at 701 by determining the presence of an empty region. Next, at 703, all vertex points of the empty region may be determined and a sequence of the vertex points may be determined.

For example, an empty region 725 may be determined. To do so, a designer may use software tools such as EDA tools or CAD tools to identify all areas within a boundary of the design that are not occupied CAD layers. From this empty region, the presence of eight total vertices may then be determined. A sequence for the vertices may then be determined to enable the creation of ECO cells. In an embodiment, the sequence may proceed in first in the x-direction, and then in the y-direction. Accordingly, the first vertex will be the vertex having the lowest x- and y-positions. The next vertex will be any vertex at a same y-position as the first vertex (if there is one), and at the next lowest x-position. Once all vertices along this x-extension have been numbered, vertices along the next y-level may be assigned. This hierarchy may result in a vertex sequence as shown in FIG. 7 for empty region 725.

Next, at 705, boxes may be extended to cover the empty region beginning from the first vertex. In an embodiment, a first box may be extended from the first vertex in the x-direction, and a second box may be extended from the first vertex in the y-direction. The area of these two boxes is compared against one another, and the box having the largest area is selected to form an ECO extension from the first vertex. Next at 707, this ECO extension may be converted into an ECO marker 735, indicating that this area is designated for ECO cells in the design.

The second auto-marker process next proceeds to 709 where a determination is made as to whether there are more vertices from which ECO extensions may be made. If yes, the second auto-marker process proceeds to 710 and phases 705-709 are repeated until ECO markers are present extending from each vertex. In an embodiment, although the process may repeat for each vertex, it may take a smaller number of ECO markers to fully cover the empty region than the total number of vertices. For example, empty region 725 may comprise eight vertices, but the region may be filled by just three ECO markers: ECO marker 735 created by extending from the first vertex; ECO marker 745 created by extending from the second vertex; and ECO marker 755, created by extending from the third vertex. Once all vertices have been analyzed, and no more space may be covered, the second auto-marker process ends at 711. The second auto-marker process may be employed to fill-in empty regions of varying complexity.

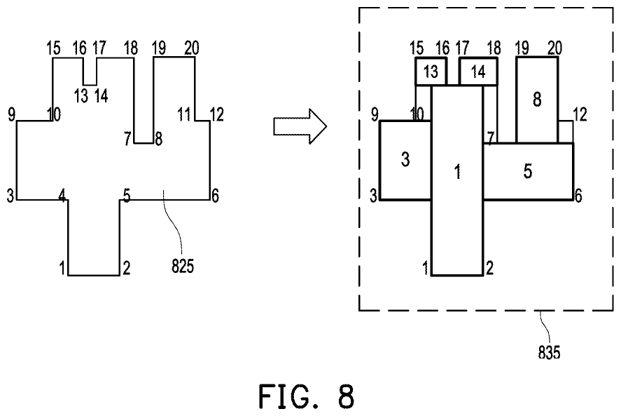

FIG. 8 is a schematic diagram depicting a second auto-marker process according to an embodiment. Here, the empty region 825 may comprise a more complex shape including twenty total vertices. Employing the second auto-marker process may result in a filled-in design 835 comprising a plurality of ECO markers.

In an embodiment, the twenty-vertex empty region may be substantially filled by six ECO markers. FIG. 8 depicts each ECO marker and shows the vertex from which they are extended in large lettering. Accordingly, a first ECO marker may extend from the first vertex, a second ECO marker may extend from the third vertex, a third ECO marker may extend from the fifth vertex, a fourth ECO marker may extend from the eight vertex, a fifth ECO marker may extend from the thirteenth vertex, and a sixth ECO marker may extend from the fourteenth vertex.

Because of the complexity of the shape of the empty region 825, the entirety of the region may not be filled by ECO markers. This may be a result of design rules that indicate ECO cells may not fit into the unoccupied slivers. However, a designer, upon realizing that slivers remain unoccupied, may attempt to fix this during a manual review and revise phase, provided that marking this area for ECO cells will not violate any rules of the design.

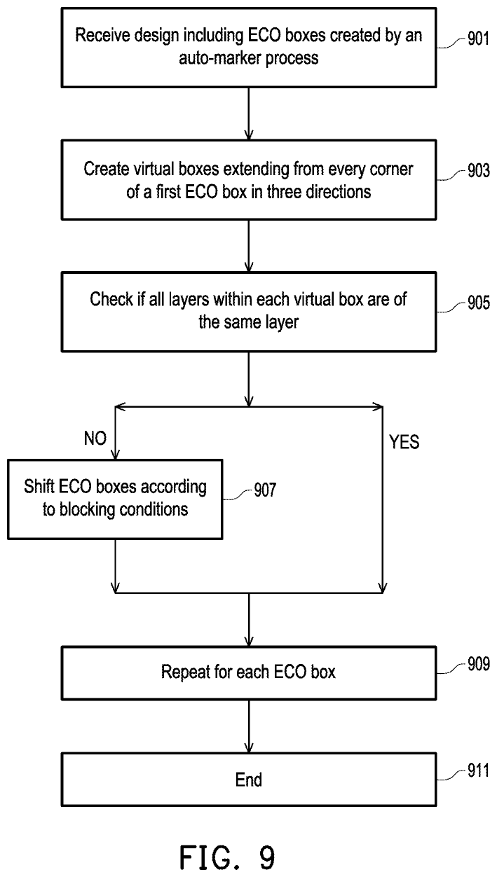

FIG. 9 is a flowchart depicting phases of a corner checking flow according to an embodiment. The corner checking flow may be provided to ensure the auto-marker process does not create ECO CAD layers that would violate design rules. In an embodiment, the corner checking flow may begin at 901 by receiving ECO boxes created during the auto-marker process. The corner checking flow may have a pre-determined priority sequence that decides what box is checked first, and how to proceed after the first box.

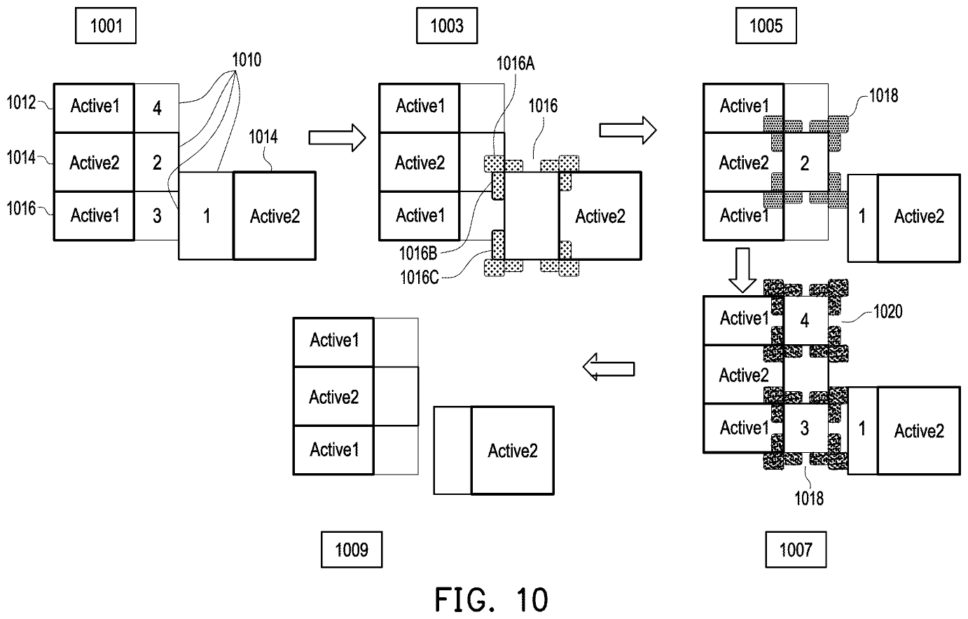

Next, at 903, virtual boxes may be created that extend from every corner a first ECO box of the design in three directions. Virtual boxes according to an embodiment are described in more detail below with respect to FIG. 10. In an embodiment, virtual boxes are first created around a first ECO box based on the pre-determined priority sequence described above. After evaluating the virtual boxes extending from the first ECO box, the process may move on to the next ECO box of the sequence.

After creating virtual boxes, these boxes may be checked at 905 to determine if all layers within each virtual box are of the same layer. For example, the virtual boxes are evaluated to see if they lie completely within a particular ECO CAD layer. If all layers within each virtual box belong to the same ECO CAD layer, the flow may proceed to 909 and this process may be repeated for each ECO box.

However, if the check performed at 905 indicates that there is a conflict and that one or more virtual boxes include layers belonging to multiple ECO CAD layers, the ECO boxes may be shifted at 907 to avoid this result. In an embodiment, this shift may occur according to pre-determined blocking conditions designed to avoid rule violations while preserving as much filled-in area as possible. After repeating this process for each ECO box at 909, the corner checking process may end at 911.

FIG. 10 is a schematic diagram depicting phases of a corner checking flow according to an embodiment. The corner checking flow may begin at 1001 with a design to be checked. In an embodiment, the design may comprise a plurality of first active cells 1012, a plurality of second active cells 1014, and a plurality of ECO boxes 1010. For example, the auto-marker process may define four ECO boxes, and they may be numbered one through four according to the pre-determined priority sequence.

Next, at 1003, virtual boxes may be created extending from a first ECO box. Virtual boxes 1016 may be created extending from each corner of the first ECO box in the priority sequence. In an embodiment, three virtual boxes may be created, each extending in a different direction, for each corner of each ECO box. For example, a first virtual box may extend diagonally from each corner, a second virtual box may start at the corner and comprise an extension in the x-direction, and a third virtual box may start at the corner and comprise an extension in the y-direction.

These virtual boxes may comprise pre-determined sizes and extensions in the x- and y-directions based on particular design considerations. For example, the first virtual box with a diagonal extension may extend 0.336 μm in the x-direction and 0.336 μm in the y-direction. The second virtual box having x-direction extension may extend 0.336 μm in the x-direction and 0.26 μm in the y-direction. The third virtual box having y-direction extension may extend 0.26 μm in the x-direction and 0.336 μm in the y-direction. These dimensions may result in the pattern of virtual boxes 1016 shown in 1003.

After virtual boxes are created, a check is performed to determine whether all layers within each virtual box are of the same layer of the device. In an embodiment this check may comprise comparing boundary regions of each virtual box with boundary regions of each active cell and each ECO box to determine whether there is a conflict. For example, consider virtual boxes labeled 1016A, 1016B, and 1016C as seen at 1003. A check of virtual box 1016A may indicate that the entirety of the layers within 1016A belong to ECO box 2. Accordingly, all layers within the virtual box are of a same ECO CAD layer and no conflict is detected.

In contrast, a check of 1016B may indicate that part of the virtual box is located within ECO box 2, while another part is located within ECO box 3. Accordingly a conflict may be detected with the boundaries of ECO box 2 and ECO box 3, and the check may determine that the layers within virtual box 1016B are not all of a same layer. Because of this conflict, the ECO boxes may be shifted in order to avoid any rule violations.

Similarly, a check of 1016C may indicate that part of the virtual box is located within ECO box 3, but other portions are located outside of that box. Here, too, this may indicate that not all of the layers within virtual box 1016C are of a same layer, and may cause ECO boxes to be shifted in order to avoid any rule violations.

Shifting of the ECO boxes may proceed according to pre-determined blocking conditions. In an embodiment, the amount the box is shifted may be determined by the amount of overlap between the virtual boxes and ECO boxes where there is a conflict. For example, ECO box 1 may be shifted by enough distance such that virtual boxes 1016 formed around ECO box 1 do not intersect with ECO boxes 2-4, and virtual boxes extending from ECO boxes 2-4 do not intersect with ECO box 1.

Such a shift is depicted at 1005. As shown, the x-direction extension of ECO box 1 may be shifted such that it does not extend to intersect with ECO boxes 1018 created around ECO box 2. Similarly, as shown at 1007, virtual boxes 1018 surrounding ECO box 3 and virtual boxes 1020 surrounding ECO box 4 do not intersect with ECO box 1 after the shift. By shifting ECO box in this manner, potential design rule violations caused by spacing violations between ECO box 1 and adjacent structures may be avoided. Accordingly, the corner checking flow may be configured to reduce DRC errors. 1009 depicts the final dimensions of each ECO box after employing a corner checking process according to an embodiment.

FIG. 11 is a flowchart and accompanying schematics depicting a DRC pre-checker according to an embodiment. The flowchart and schematics shown depicted in FIG. 11 may be the same as those described above with respect to FIG. 2. In an embodiment, the DRC pre-checker 1110 may be employed at any stage before cells are inserted into the design. Accordingly, a designer may know at any point during the creation of ECO cells whether a design rule may be violated. This may alert the designer to issues earlier than if the DRC pre-check is employed only as a last measure before inserting ECO cells, thereby saving time and leading to a more efficient design process. The DRC pre-checker 1110 may check for at least 187 specific design rules that are maintained by the pre-checker. By employing this DRC pre-check process, designers may ensure that failures related to various design rule violations may be avoided.

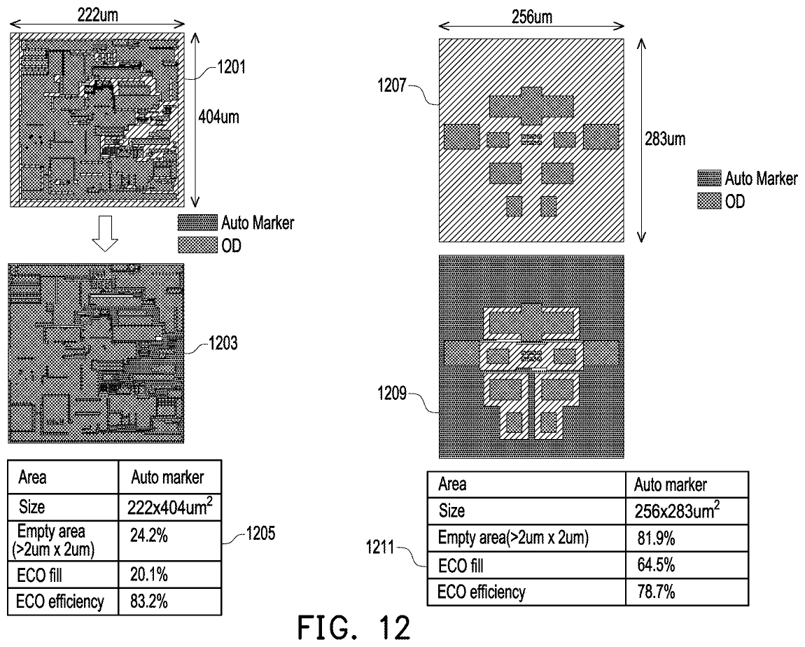

FIG. 12 shows schematic diagrams depicting a layout of a design after an analog ECO process according to embodiments. The diagrams show the efficiency the fill-in process of analog ECO flows described herein. Layout 1201 depicts a first layout prior to an analog ECO flow. Layout 1203 depicts that same layout after employing an analog ECO flow according to embodiments described herein, in which the empty space is filled by ECO cells. The percentage of empty space that is filled-in by ECO cells after the analog ECO flow may be deemed the ECO fill-in efficiency of the process. The ECO fill-in efficiency of embodiments described herein may be greater than 70%. In some embodiments, the ECO fill-in efficiency may even be greater than 80%.

Table 1205 describes the efficiency of this process. In an embodiment, layout 1201 may comprise empty space taking up 24.2% of the overall area. After ECO fill-in, ECO cells may fill-in up to 20.1% of the overall area, indicating an ECO fill-in efficiency of 82.3%.

Layout 1207 depicts a second layout prior to an analog ECO flow. Layout 1209 depicts that same layout after an analog ECO flow process is employed and the empty space is filled by ECO fills. In an embodiment, the layout may comprise diodes and BJTs. In order to avoid DRC violations related by placing cells and/or metal layers too close to these components, larger spacing regions may surround these components.

Table 1211 describes the efficiency of this process. Layout 1207 may comprise empty space taking up 81.9% of the overall area. After ECO fill-in, ECO cells may fill-in up to 64.5% of the overall area, indicating an ECO fill-in efficiency of 78.7%. By achieving high levels of ECO fill-in efficiency, the analog ECO flows described herein may facilitate efficient ECOs in response to design changes.

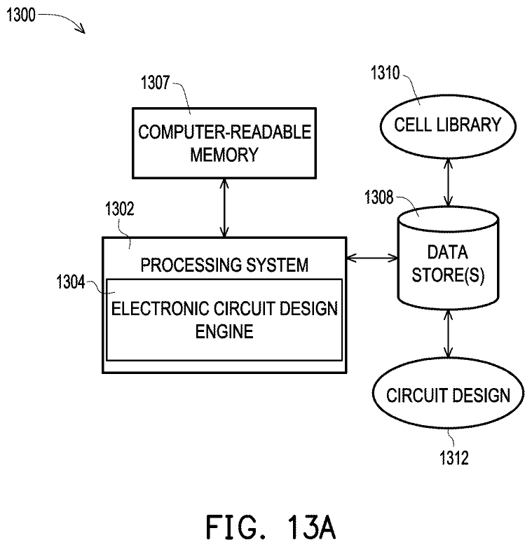

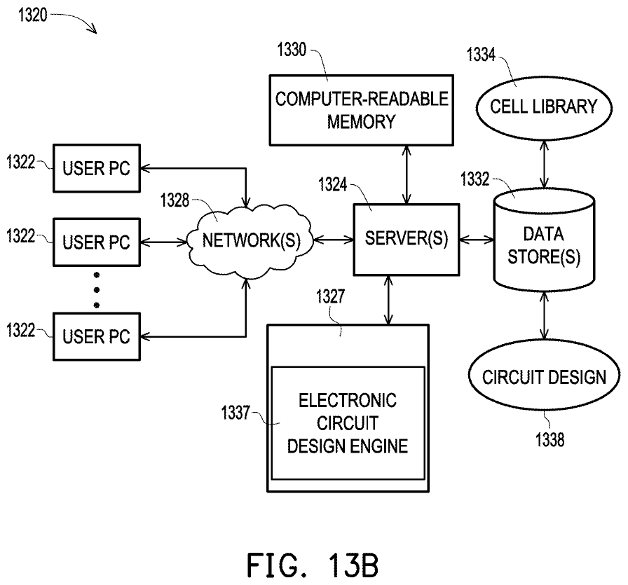

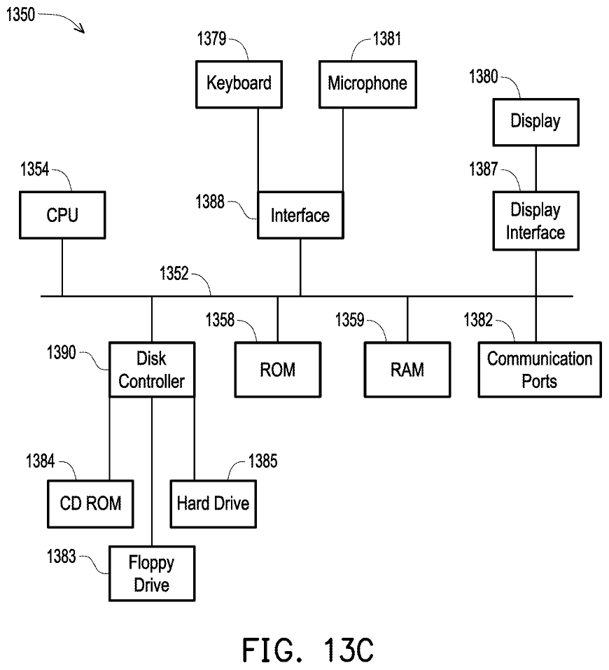

FIGS. 13A, 13B, and 13C depict example systems for implementing the approaches described herein for designing integrated circuits. For example, FIG. 13A depicts an exemplary system 1300 that includes a standalone computer architecture where a processing system 1302 (e.g., one or more computer processors located in a given computer or in multiple computers that may be separate and distinct from one another) includes a computer-implemented electronic circuit design engine 1304 being executed on the processing system 1302. The processing system 1302 has access to a computer-readable memory 1307 in addition to one or more data stores 1308. The one or more processors of processing system 1302 may be in communication with the computer-readable memory 1307 which may store instructions that, when executed, command the one or more processors to execute the operations of the methods described herein. The one or more data stores 1308 may include a cell library database 1310 as well as a circuit design database 1312. In an embodiment, cell library database 1310 may comprise an analog cell library. The processing system 1302 may be a distributed parallel computing environment, which may be used to handle very large-scale data sets.

FIG. 13B depicts a system 1320 that includes a client-server architecture. One or more user PCs 1322 access one or more servers 1324 running an electronic circuit design engine 1337 on a processing system 1327 via one or more networks 1328. The one or more servers 1324 may access a computer-readable memory 1330 as well as one or more data stores 1332. The one or more data stores 1332 may include a cell library database 1334 as well as a circuit design database 1338.

FIG. 13C shows a block diagram of exemplary hardware for a standalone computer architecture 1350, such as the architecture depicted in FIG. 13A that may be used to include and/or implement the program instructions of system embodiments of the present disclosure. A bus 1352 may serve as the information highway interconnecting the other illustrated components of the hardware. A processing system 1354 labeled CPU (central processing unit) (e.g., one or more computer processors at a given computer or at multiple computers), may perform calculations and logic operations required to execute a program. A non-transitory processor-readable storage medium, such as read only memory (ROM) 1358 and random-access memory (RAM) 1359, may be in communication with the processing system 1354 and may include one or more programming instructions for performing the method of designing an integrated circuit. Program instructions may be stored on a non-transitory computer-readable storage medium such as a magnetic disk, optical disk, recordable memory device, flash memory, or other physical storage medium.

In FIGS. 13A, 13B, and 13C, computer readable memories 1307, 1330, 1358, 1359 or data stores 1308, 1332, 1383, 1384, 1388 may include one or more data structures for storing and associating various data used in the example systems for designing an integrated circuit. For example, a data structure stored in any of the aforementioned locations may be used to store data from XML files, initial parameters, and/or data for other variables described herein. A disk controller 1390 interfaces one or more optional disk drives to the system bus 1352. These disk drives may be external or internal floppy disk drives such as 1383, external or internal CD-ROM, CD-R. CD-RW, or DVD drives such as 1384, or external or internal hard drives 1385. In addition to physical drives, the system bus 1352 may be in communication with cloud-based virtual drives. As indicated previously, these various disk drives and disk controllers are optional devices.

Each of the element managers, real-time data buffer, conveyors, file input processor, database index shared access memory loader, reference data buffer and data managers may include a software application stored in one or more of the disk drives connected to the disk controller 1390, the ROM 1358 and/or the RAM 1359. The processor 1354 may access one or more components as required. A display interface 1387 may permit information from the bus 1352 to be displayed on a display 1880 in audio, graphic, or alphanumeric format. Communication with external devices may optionally occur using various communication ports 1382. In addition to these computer-type components, the hardware may also include data input devices, such as a keyboard 1379. or other input device 1381, such as a microphone, remote control, pointer, mouse and/or joystick.

Additionally, the methods and systems described herein may be implemented on many different types of processing devices by program code comprising program instructions that are executable by the device processing subsystem. The software program instructions may include source code, object code, machine code, or any other stored data that is operable to cause a processing system to perform the methods and operations described herein and may be provided in any suitable language such as C. C++, JAVA, for example, or any other suitable programming language. Other implementations may also be used, however, such as firmware or even appropriately designed hardware configured to carry out the methods and systems described herein.

The systems' and methods' data (e.g., associations, mappings, data input, data output, intermediate data results, final data results, etc.) may be stored and implemented in one or more different types of computer-implemented data stores, such as different types of storage devices and programming constructs (e.g., RAM, ROM, Flash memory, flat files, databases, programming data structures, programming variables, IF-THEN (or similar type) statement constructs, etc.). It is noted that data structures describe formats for use in organizing and storing data in databases, programs, memory, or other computer-readable media for use by a computer program.

The computer components, software modules, functions, data stores and data structures described herein may be connected directly or indirectly to each other in order to allow the flow of data needed for their operations. It is also noted that a module or processor includes but is not limited to a unit of code that performs a software operation, and can be implemented for example as a subroutine unit of code, or as a software function unit of code, or as an object (as in an object-oriented paradigm), or as an applet, or in a computer script language, or as another type of computer code. The software components and/or functionality may be located on a single computer or distributed across multiple computers depending upon the situation at hand.

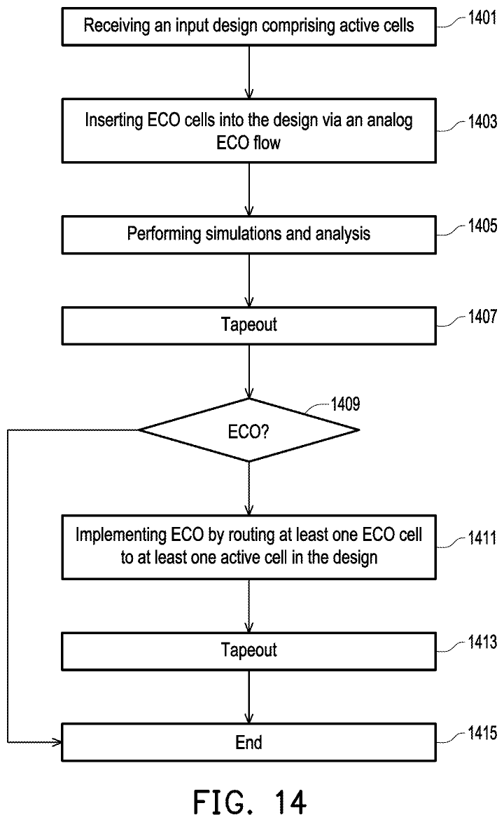

FIG. 14 is a flowchart depicting a method of implementing a design change to an integrated circuit according to an embodiment. As described above with respect to FIG. 2, methods of designing an integrated circuit incorporating an analog ECO flow may proceed to tapeout without the need to implement design changes via an ECO. After tapeout, however, new information may arise indicating to the designer that an ECO implementing a design change may increase the performance of the device.

A method of implementing such a change may begin at 1401 where an input design may be received. The input design may comprise a plurality of active cells interconnected and organized to perform desired functions. In an embodiment, one or more of the active cells may comprise analog cells.

Next, at 1403, ECO cells may be inserted into the design via an analog ECO flow. The analog ECO flow may be analog ECO flow 250 described above with respect to FIG. 2. This process may comprise an auto-marker flow that surrounds active cells with ECO CAD layers that may then be inserted into the design as ECO cells.

After inserting the ECO cells, simulations may be run to determine the performance of the design and these simulations may be analyzed to ensure proper functioning. If the analysis reveals any problems, a designer may alter the design accordingly. If the design passes all tests, the method may proceed to tapeout at 1407. During tapeout, the design may be processed and fabricated. However, the method may continue to 1409 where a determination may be made as to whether an ECO will improve the design.

An ECO may be desired for a number of reasons, including as a response to errors or failures detected in devices fabricated from the design, to implement new features into the design, or to improve performance. If it is determined that an ECO will not improve the design, the proceeds to end at 1415. If, instead, it is determined at 1409 that an ECO may be advantageous, the ECO may be implemented at 1411.

Implementing an ECO may comprise using ECO cells of the design to enact the changes. These cells are initially not routed together with any active components of the design. But, to implement an ECO, at least one ECO may be routed to connect to at least one active cell of the design. The presence of these ECO cells dispersed throughout the design allows such an ECO to be implemented without requiring extensive re-design. After implementing the ECO, the revised design is taped out at 1413, and the method ends at 1415.

Methods, computer-readable mediums, and systems are described herein. In an example method of designing an integrated circuit, an initial design is received. An auto-marker process is performed which includes a first auto-marker process, an enhanced auto-marker process and a second auto-marker process. The first auto-marker process surrounds a first plurality of active cells of the design with first CAD layers corresponding to a first plurality of ECO cells. The enhanced auto-marker process covers irregular shapes of the design with second CAD layers corresponding to a second plurality of ECO cells. And the second auto-marker process fills empty areas of the design with third CAD layers corresponding to a third plurality of ECO cells. The method further includes filling the design with the first plurality of ECO cells, the second plurality of ECO cells, and the third plurality of ECO cells.

In another example, a non-transitory computer-readable encoded with memory storing instructions for fabricating an integrated circuit is provided. When executed, these instructions initiate an auto-marker to fill-in an initial circuit design with a plurality of ECO cells thereby forming an updated design. Dummy patterns configured to prevent dishing during fabrication are inserted into the updated design. A final DRC check, RC-extraction, and post-layout simulations are performed. The executed instructions cause an integrated circuit to be fabricated based on the updated design.

In an example system for making a design change to an integrated circuit, an input design comprising a plurality of active cells is received. ECO cells are inserted into the input design via an analog ECO flow to form an updated design. An integrated circuit is fabricated based on the updated design. An ECO is then implemented by routing at least one ECO cell of the updated design to at least one active cell of the updated design, thereby creating a revised design. A revised integrated circuit is fabricated from the revised design.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes herein without departing from the spirit and scope of the present disclosure.

It is claimed:

1. A method of designing an integrated circuit comprising:
receiving an initial design;
performing an auto-marker process, comprising:
performing a first auto-marker process to surround a first plurality of active cells of the design with first computer-aided design (CAD) layers corresponding to a first plurality of engineering change order (ECO) cells;
performing an enhanced auto-marker process to cover irregular shapes of the design with second CAD layers corresponding to a second plurality of ECO cells;
performing a second auto-marker process to fill empty areas of the design with third CAD layers corresponding to a third plurality of ECO cells; and
filling the design with the first plurality of ECO cells, the second plurality of ECO cells, and the third plurality of ECO cells.

2. The method of claim 1, further comprising:
receiving, from a user, revisions to one of the first CAD layers, second CAD layers, and third CAD layers; and
modifying the design in response to the revisions.

3. The method of claim 2, further comprising:
receiving, from the user, instructions to add decoupling capacitor (decap) layers corresponding to an ECO decap cell to the design; and
modifying the design in response to the instructions.

4. The method of claim 3, further comprising:
after modifying the design in response to the instructions, performing a design rule check (DRC) pre-check on the design; and
receiving, from the user, a second set of revisions in response to a failure of the DRC pre-check.

5. The method of claim 1, further comprising:
performing a design rule check (DRC) pre-check on the initial design, prior to performing the auto-marker process; and
modifying the initial design in response to a failure of the DRC pre-check.

6. The method of claim 1, wherein the first auto-marker process comprises:
generating first ECO boxes extending, in a first direction, from each of the plurality of active cells;
extending the first ECO boxes in the first direction until a conflict is detected;
generating second ECO boxes extending, in a second direction, from each of the plurality of active cells; and
extending the second ECO boxes in the second direction until a conflict is detected.

7. The method of claim 1, wherein the second auto-marker process comprises:
(a) determining the presence of an empty region;
(b) detecting all vertex points of the empty region and determining a sequence of the vertex points;
(c) extending a first ECO box from a first vertex point in a first direction and extending a second ECO box from the first vertex point in a second direction;
(d) comparing an area of the first ECO box and the second ECO box;
(e) converting the box having a larger area into an ECO marker; and
(f) repeating steps (c)-(e) for each vertex point.

8. The method of claim 1, further comprising:
after filling the design with the first plurality of ECO cells, the second plurality of ECO cells, and the third plurality of ECO cells, performing RC extraction and post-layout simulations on the design.

9. The method of claim 1, wherein the active cells are analog cells.

10. A non-transitory computer-readable medium encoded with memory storing instructions for fabricating an integrated circuit, which when executed result in operations comprising:
initiating an auto-marker process to fill-in an initial circuit design with a plurality of ECO cells, thereby forming an updated design;
inserting dummy patterns, wherein the dummy patterns are configured to prevent dishing during fabrication;
performing a final design rule check (DRC);
performing RC-extraction and post-layout simulations; and
causing an integrated circuit to be fabricated from the updated design.

11. The non-transitory computer-readable medium of claim 10, wherein the initial design comprises a plurality of analog cells.

12. The non-transitory computer-readable medium of claim 11, wherein the auto-marker process surrounds the plurality of analog cells with the plurality of ECO cells.

13. The non-transitory computer-readable medium of claim 10, the operations further comprising initiating a corner checking flow configured to reduce DRC error.

14. The non-transitory computer-readable medium of claim 10, wherein the updated design comprises an ECO fill-in efficiency of greater than 70%.

15. The non-transitory computer-readable medium of claim 10, the operations further comprising adding at least one ECO decap layer to the initial design.

16. The non-transitory computer-readable medium of claim 15, wherein the fill-in of the initial design further comprises filling-in the at least one ECO decap layer to form at least one ECO decap cell in the updated design.

17. The non-transitory computer-readable medium of claim 10, wherein the updated design further comprises a plurality of active cells; and
the plurality of ECO cells are not routed to connect to any of the plurality of active cells in the updated design.

18. A computer-implemented system for making a design change to an integrated circuit, comprising:
one or more processors; and
computer-readable memory in communication with the one or more processors and encoded with instructions for commanding the one or more processors to execute steps comprising:
receiving an input design comprising a plurality of active cells;
inserting ECO cells into the design via an analog ECO flow to form an updated design;
fabricating an integrated circuit based on the updated design;
implementing an ECO by routing at least one ECO cell of the updated design to at least one active cell of the updated design, thereby creating a revised design; and
fabricating a revised integrated circuit based on the revised design.

19. The system of claim 18, wherein at least one active cell of the plurality of active cells comprises an analog cell.

20. The system of claim 18, wherein the analog ECO flow comprises:
performing an auto-marker process to surround the plurality of active cells with a plurality of ECO cells, wherein the auto-marker process comprises:
generating first ECO boxes extending, in a first direction, from each of the plurality of active cells;
extending the first ECO boxes in the first direction until a conflict is detected;
generating second ECO boxes extending, in a second direction, from each of the plurality of active cells; and
extending the second ECO boxes in the second direction until a conflict is detected.
